(19) United States
(12) Patent Application Publication
(10) Pub. No.: US 2024/0183895 A1
(43) Pub. Date: Jun. 6, 2024

(54) PROBE CARD TRANSPORTING APPARATUS AND METHOD

(71) Applicant: SEMES CO., LTD., Cheonan-si (KR)

(72) Inventors: Ho Young LEE, Gyeonggi-do (KR); Seung Chan LEE, Gyeonggi-do (KR)

(73) Assignee: SEMES CO., LTD., Cheonan-si (KR)

(21) Appl. No.: 18/503,840

(22) Filed: Nov. 7, 2023

(30) Foreign Application Priority Data
Dec. 6, 2022 (KR) 10-2022-0168502

(51) Int. Cl. G01R 31/26; G01R 1/073

(52) U.S. Cl. CPC G01R 31/2601; G01R 1/07314

(57) ABSTRACT

A probe card transporting apparatus and method capable of loading a plurality of probe cards and enabling the replacement of probe cards independently are provided. The probe card transporting apparatus includes: a first loading module where a first probe card, which is a replacement probe card, is mounted; a second loading module where a second probe card to be replaced is mounted; and a hand gripper module withdrawing the second probe card from a probe station for semiconductor testing or inserting the first probe card into the probe station.

### CROSS-REFERENCE TO RELATED APPLICATION

This application claims priority from Korean Patent Application No. 10-2022-0168502 filed on Dec. 6, 2022 in the Korean Intellectual Property Office, and all the benefits accruing therefrom under 35 U.S.C. 119, the contents of which in its entirety are herein incorporated by reference.

### BACKGROUND

### 1. Field

The present disclosure relates to a probe card transporting apparatus and method, and more particularly, to a probe card transporting apparatus and method, which can be utilized within a semiconductor fabrication plant.

### 2. Description of the Related Art

Semiconductor manufacturing processes may be continuously carried out within semiconductor fabrication equipment and may be classified into front-end processes and back-end processes. Here, the front-end processes refer to processes of forming circuit patterns on a wafer to complete a semiconductor chip, while the back-end processes refer to processes of evaluating the performance of a completed product obtained through the front-end processes.

The semiconductor fabrication equipment can be installed within a semiconductor fabrication plant called a fab. Wafers go through various processes such as deposition, photolithography, etching, ion implantation, cleaning, packaging, and inspection, sequentially moving to equipment where each process is performed to produce semiconductors.

Once a semiconductor device is obtained through deposition, photolithography, etching, and packaging processes, an inspection process may be carried out at a probe station to test the electrical characteristics of the semiconductor device. A probe card transporting robot can serve to transport probe cards to the probe station according to the characteristics of the semiconductor device, enabling the inspection process within the probe station.

However, conventional probe card transporting robots can only load a single probe card, and cannot load two or more probe cards. Therefore, there is an issue where two or more probe card transporting robots are needed to change probe cards.

### SUMMARY

Aspects of the present disclosure provide a probe card transporting apparatus and method capable of loading a plurality of probe cards and enabling the replacement of probe cards independently.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of the present disclosure, a probe card transporting apparatus includes: a first loading module where a first probe card, which is a replacement probe card, is mounted; a second loading module where a second probe card to be replaced is mounted; and a hand gripper module withdrawing the second probe card from a probe station for semiconductor testing or inserting the first probe card into the probe station.

According to another aspect of the present disclosure, a probe card transporting apparatus includes: a first loading module where a first probe card, which is a replacement probe card, is mounted; a second loading module where a second probe card to be replaced is mounted; and a hand gripper module withdrawing the second probe card from a probe station for semiconductor testing or inserting the first probe card into the probe station, wherein when the first probe card is provided, the probe card transporting apparatus autonomously navigates to a location where the probe station is positioned, the first loading module is disposed on a higher level than the second loading module and moves to one of a rotating manner and a linear manner when the second probe card is mounted on the second loading module, and the hand gripper module is disposed on a higher level than the first and second loading modules and loads or unloads the first and second probe cards by descending to a level where the first and second loading modules are positioned.

According to another aspect of the present disclosure, a probe card transporting method includes: withdrawing, by a hand gripper module, a second probe card from a probe station; moving a first loading module with a first probe card mounted therein; loading, by the hand gripper module, the second probe card on a second loading module, which is disposed below the first loading module; unloading, by the hand gripper module, the first probe card on the first loading module; and inserting, by the hand gripper module, the first probe card into the probe station.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a block diagram illustrating the internal configuration of a system for semiconductor operation testing;

FIG. 2 is a schematic view illustrating the internal configuration of a probe station of the system of FIG. 1;

FIG. 3 is a first exemplary schematic view illustrating the internal configuration of the probe card transporting apparatus of the system of FIG. 1;

FIG. 4 is a schematic diagram illustrating the internal configuration of a driving unit of the probe card transporting apparatus;

FIG. 5 is a second exemplary schematic view illustrating the internal configuration of the probe card transporting apparatus of the system of FIG. 1;

FIG. 6 is a third exemplary schematic view illustrating the internal structure of the probe card transporting apparatus of the system of FIG. 1;

FIG. 7 is a first exemplary schematic view illustrating the operating principle of a first loading module of the probe card transporting apparatus;

FIG. 8 is a second exemplary schematic view illustrating the operating principle of the first loading module of the probe card transporting apparatus;

FIG. 9 is a first exemplary schematic view illustrating the operating principles of the first loading module and a second loading module of the probe card transporting apparatus;

FIG. 10 is a second exemplary schematic view illustrating the operating principles of the first and second loading modules of the probe card transporting apparatus;

FIG. 11 is a first exemplary schematic view illustrating the operating principle of the second loading module of the probe card transporting apparatus;

FIG. 12 is a second exemplary schematic view illustrating the operating principle of the second loading module of the probe card transporting apparatus;

FIG. 13 is an exemplary schematic view illustrating the operating principle of a hand gripper module of the probe card transporting apparatus;

FIG. 14 is a first exemplary schematic view illustrating the performance of the hand gripper module of the probe card transporting apparatus;

FIG. 15 is a second exemplary schematic view illustrating the performance of the hand gripper module of the probe card transporting apparatus;

FIG. 16 is a first exemplary schematic view illustrating various functionalities of a manipulator unit of the probe card transporting apparatus;

FIG. 17 is a second exemplary view describing various functionalities of the manipulation unit of the probe card transporting apparatus;

FIG. 18 is a first exemplary schematic view illustrating how to determine whether the mounting status of a probe card is favorable;

FIG. 19 is a second exemplary schematic view illustrating how to determine whether the mounting status of a probe card is favorable;

FIG. 20 is a fourth exemplary schematic view illustrating the internal configuration of the probe card transporting apparatus of the system of FIG. 1;

FIG. 21 is a fifth exemplary schematic view illustrating the internal configuration of the probe card transporting apparatus of the system of FIG. 1;

FIG. 22 is a flowchart illustrating a method of replacing probe cards according to a first embodiment of the present disclosure;

FIG. 23 is a flowchart illustrating a method of replacing probe cards according to a second embodiment of the present disclosure; and

FIG. 24 is a flowchart illustrating a method of replacing probe cards according to a third embodiment of the present disclosure.

### DETAILED DESCRIPTION

Embodiments of the present disclosure will hereinafter be described with reference to the accompanying drawings. The same reference numerals are used for the same components in the drawings, and redundant descriptions thereof are omitted.

The present disclosure relates to a probe card transporting apparatus that can be used within a semiconductor fabrication plant (or a fab) and features the ability to load multiple probe cards. According to the present disclosure, even when it is necessary to replace probe cards within a probe station, the provision of a single probe card transporting device is sufficient. This consequently results in space savings within the fab and enhances the utility of the probe card transporting apparatus.

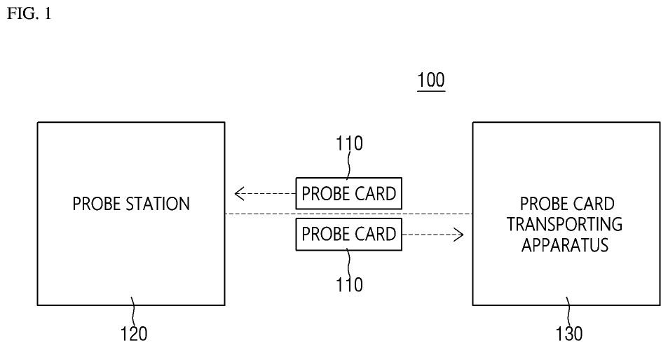

FIG. 1 is a block diagram illustrating the internal configuration of a system for semiconductor operation testing. Referring to FIG. 1, a system 100 may be configured to include probe cards 110, a probe station 120, and a probe card transporting apparatus 130.

The probe cards 110 connect a substrate (e.g., a wafer) and test equipment to allow the test equipment to inspect the operation of semiconductors. Each of the probe cards 110 may be equipped with probes that contact the substrate and transmit electrical signals to the substrate. The test equipment may use electrical signals transmitted to and received from the substrate to determine the quality of the semiconductors.

The probe station 120 inspects the electrical characteristics of the substrate with multiple semiconductors using the probe cards 110 and the test equipment. For this purpose, the probe station 120 may be configured to include a test chamber 210, test equipment 220, a substrate support unit 230, and a camera module 240.

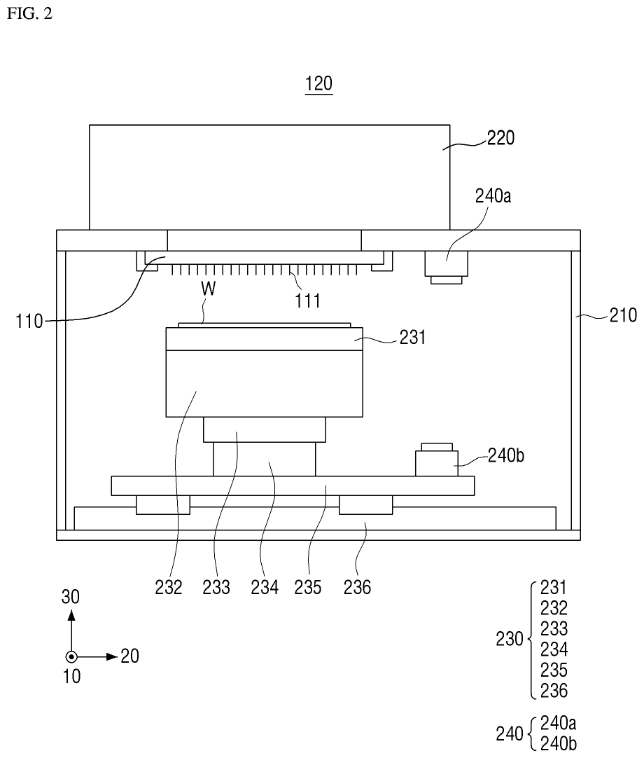

FIG. 2 is a schematic view illustrating the internal configuration of the probe station of the system of FIG. 1.

Referring to FIG. 2, the probe station 120 may perform a testing process to inspect the electrical characteristics of a substrate W. The test chamber 210 provides the space where such testing process is performed.

A probe card 110 may be installed at an upper part within the test chamber 210. As mentioned earlier, the probe card 110 may be connected to the test equipment 220 to inspect the electrical characteristics of the substrate W. The test equipment 220 may be disposed in proximity to an outer upper surface of the test chamber 210 to be connected with the probe card 110.

The probe card 110 may include one or more probes 111 on its lower surface. The probe 111 may apply test signals to each semiconductor chip on the substrate W under the control of the test equipment 220. Once alignment between the substrate W and the probe card 110 is completed by the camera module 240, the probes 111 may come into contact with test pads (i.e., semiconductor chips) on the substrate W to apply test signals.

The test equipment 220 uses the probe card 110 to inspect the electrical characteristics of the substrate W. The test equipment 220 may apply electrical signals to each semiconductor chip on the substrate W via the probes 111 on the probe card 110, and may inspect the electrical characteristics of the substrate W based on electrical signals returning from each semiconductor chip.

The substrate support unit 230 is disposed within the test chamber 210 and supports the substrate W. The substrate support unit 230 may adjust the position of the substrate W to allow for horizontal movement (either in a first direction 10 or a second direction 20) within the test chamber 210. The substrate support unit 230 may also adjust the position of the substrate W to allow for vertical movement (in a third direction 30) within the test chamber 210.

For horizontal movement, the substrate support unit 230 may adjust the position of the substrate W so that the test pads on the substrate W are aligned with the probes 111 on the probe card 110. For vertical movement, the substrate support unit 230 may adjust the position of the substrate W so that the test pads come into contact with the probes 111 on the probe card 110. Once the alignment between the substrate W and the probe card 110 is completed by an upper alignment camera 240a and a lower alignment camera 240b, the substrate support unit 230 may adjust the position of the substrate W for vertical movement.

The substrate support unit 230 may be configured to include a chucking module 232, a rotary operating module 233, a vertical operating module 234, a chuck stage 235, and a horizontal operating module 236.

The chucking module 232 supports the substrate W. The chucking module 232 may be disposed within the test chamber 210 to face the probe card 110 and may include a chuck plate 231 on its upper surface. Here, the chuck plate 231 may provide a mounting surface for the substrate W to be mounted thereon.

Although not illustrated in FIG. 2, the chucking module 232 may further include a vacuum formation plate. The vacuum formation plate may have vacuum suction capabilities and may adhere the substrate W that has landed on the chuck plate 231 onto the chuck plate 231. If the chucking module 232 includes the vacuum formation plate, the vacuum formation plate may be positioned below the chuck plate 231.

The rotary operating module 233 rotates the chucking module 232. The rotary operating module 233 may be positioned below the chucking module 232 and may rotate the chucking module to align the test pads on the substrate W with the probes 111 on the probe card 110.

The vertical operating module 234 adjusts the vertical position (in the third direction 30) of the chucking module 232. The vertical operating module 234 may be positioned below the rotary operating module 233 and may adjust the vertical position of the chucking module 232 to bring the test pads on the substrate W into contact with the probes 111 on the probe card 110.

The chuck stage 235 supports the chucking module 232, the rotary operating module 233, and the vertical operating module 234. The chuck stage 235 may be positioned below the vertical operating module 234.

The horizontal operating module 236 adjusts the horizontal position (in the first or second direction 10 or 20) of the chucking module 232. The horizontal operating module 236 may be positioned below the chuck stage 235 and may adjust the horizontal position of the chucking module 232 to align the test pads on the substrate W with the probes 111 on the probe card 110.

The camera module 240 aligns the substrate W and the probe card 110. The camera module 240 may include the upper and lower alignment cameras 240a and 240b.

The upper alignment camera 240a is positioned on the inner upper side of the test chamber 210. The upper alignment camera 240a may capture and acquire an image of patterns on the substrate W in a downward direction from the inner upper side of the test chamber 210. Although not illustrated in FIG. 2, the upper alignment camera 240a may be moved horizontally (in the first or second direction 10 or 20) by an operating module with a bridge-like structure.

The lower alignment camera 240b is positioned on the inner lower side of the test chamber 210. The lower alignment camera 240b may capture and acquire an image of the probes 111 on the probe card 110 in an upward direction from the inner lower side of the test chamber 210. The images acquired by the upper and lower alignment cameras 240a and 240b may be utilized to align the substrate W and the probe card 110.

Although not illustrated in FIG. 2, the probe station 120 may further include heating and cooling units to regulate the temperature of the substrate W. Here, the heating unit heats the chuck plate 231, while the cooling unit supplies a coolant into the chuck plate 231 to cool the chuck plate 231. The heating and cooling units may be provided either outside or inside the test chamber 210, and the probe station 120 may control the heating and cooling units to ensure that the temperature of the substrate W is appropriate for a testing process.

Referring again to FIG. 1, the probe card transporting apparatus 130 replaces the probe cards 110. For this purpose, the probe card transporting apparatus 130 may transport the probe cards 110 to the location where the probe station 120 is positioned, and may also load the probe cards 110 into or unload the probe cards 110 from the probe station 120.

The probe card transporting apparatus 130 may be provided as a vehicle or robot that autonomously navigates within the semiconductor fabrication plant to transport the probe cards 110 to the location where the probe station 120 is positioned. For example, the probe card transporting apparatus 130 may be configured as an automatic guided vehicle (AGV), which is an industrial vehicle capable of moving automatically without a driver, or as an autonomous mobile robot (AMR).

The probe card transporting apparatus 130 may include a gripper to load and unload the probe cards 110. By using the gripper, the probe card transporting apparatus 130 may bring the probe cards 110 into the probe station 120 and may also remove the probe cards 110 from within the probe station 120. Although not illustrated in FIG. 2, the test chamber 210 may include a window on a sidewall thereof that can open and close, allowing for the entry and exit of the probe cards 110.

To replace the probe cards 110, i.e., to transport the probe cards 110 to where the probe station 120 is positioned and to load or unload the probe cards 110 into or from the probe station 120, the probe card transporting apparatus 130 may include a driving unit and a manipulator unit.

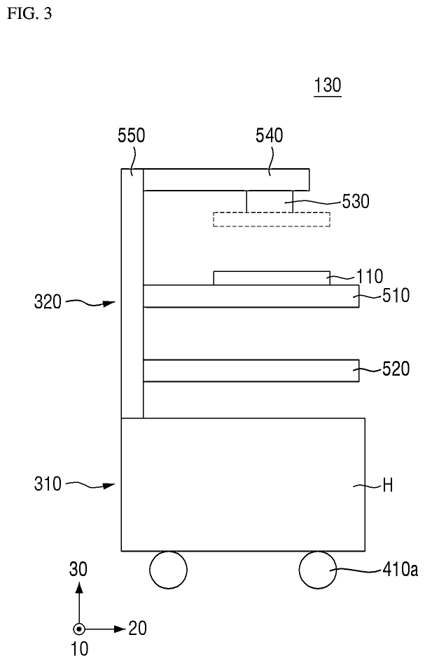

FIG. 3 is a first exemplary schematic view illustrating the internal configuration of the probe card transporting apparatus of the system of FIG. 1. Referring to FIG. 3, the probe card transporting apparatus 130 can be configured to include a driving unit 310 and a manipulator unit 320.

The driving Unit 310 moves the probe card transporting apparatus 130 to its destination. Accordingly, the probe card transporting apparatus 130 may transport the probe cards 110 to the location where the probe station 120 is positioned.

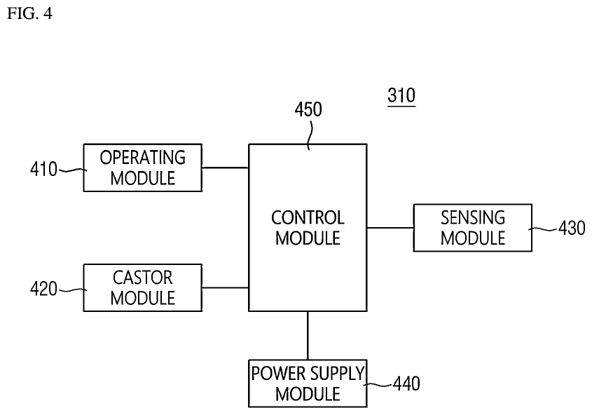

FIG. 4 is a schematic diagram illustrating the internal configuration of the driving unit of the probe card transporting apparatus. Referring to FIG. 4, the driving unit 310 may be configured to include an operating module 410, a caster module 420, a sensing module 430, a power supply module 440, and a control module 450.

The operating module 410 includes a plurality of first wheels 410a and moves the probe card transporting apparatus 130 along a predetermined path to the destination through the first wheels 410a. The operating module 410 may use power supplied from the power supply module 440 and may operate under the control of the control module 450.

The caster module 420 includes a plurality of second wheels, which are smaller in size than the first wheels 410a and alter the driving condition of the probe card transporting apparatus 130 through the second wheels. The caster module 420 may be formed of a material capable of absorbing impacts or vibrations to allow for damping in relation to the driving direction or speed of the probe card transporting apparatus 130. Accordingly, the stability of the probe card transporting apparatus 130 can be improved when the probe card transporting apparatus 130 moves at high speed. While not explicitly illustrated in FIGS. 3 and 4, the caster module 420, like the operating module 410, may be installed on the lower surface of a housing H and may be located more externally than the operating module 410. Alternatively, the caster module 420 may not be included in the driving unit 310.

The sensing module 430, which is for autonomous navigation of the probe card transporting apparatus 130, may, for example, include a Light Detection and Ranging (LiDAR) sensor. The sensing module 430 may be installed on the front side of the housing H, but alternatively, other sensing modules 430 may be further installed on other sides of the housing H, such as the lateral, rear, or upper sides of the housing H, to enhance sensing efficiency. The installation location, type, and number of sensing modules 430 are not limited and may vary depending on the purpose of use.

For example, the sensing module 430 may detect obstacles while the probe card transporting apparatus 130 is moving to the destination. Accordingly, the probe card transporting apparatus 130 can prevent dropping of the probe cards 110 or damage to the probe cards 110 due to collisions with obstacles.

The power supply module 440 provides power to each of the components of the driving unit 310, such as the operating module 410, the caster module 420, the sensing module 430, and the control module 450. The power supply module 440 may provide power to each of the components of the driving unit 310 continuously or optionally as needed.

The control module 450 controls the overall operations of the components of the driving unit 310. The control module 450 may also control the overall operations of the components of the manipulation unit 320, but the present disclosure is not limited thereto. Alternatively, separate control modules may be provided for controlling the overall operations of the components of the driving unit 310 and for controlling the overall operations of the components of the manipulation unit 320.

Referring back to FIG. 3, the manipulation unit 320 grips and transports the probe cards 110 while the probe card transporting apparatus 130 is moving to where the probe station 120 is located. Once the probe card transporting apparatus 130 arrives at where the probe station 120 is located, the manipulation unit 320 loads or unloads the probe cards 110 onto or from the probe station 120.

Conventionally, in a case where the probe cards 110 are for use in a semiconductor testing process, humans manually load the probe cards 110 onto a cart and transport the cart to where the probe station 120 is located for direct loading. Conversely, the probe card transporting apparatus 130, which is a system that combines a self-driving robot, i.e., the driving unit 310, and a robot capable of manipulating the probe cards 110, i.e., the manipulation unit 320, is capable of being able to fully automate the distribution and collection of the probe cards 110 without human intervention.

The manipulation unit 320 may include a plurality of loading modules to enable the loading and unloading of probe cards to be performed at the same time. The manipulation unit 320 is illustrated in FIG. 3 as including two loading modules, i.e., first and second loading modules 510 and 520, but the present disclosure is not limited thereto. Alternatively, the manipulator unit 320 may include three or more loading modules.

The manipulator unit 320 will hereinafter be described as including two loading modules, i.e., the first and second loading modules 510 and 520).

The manipulation unit 320 may be configured to include the first loading module 510, the second loading module 520, a hand gripper module 530, a robot arm module 540, and a support module 550.

The first loading module 510 is for loading the probe cards 110 while the probe card transporting apparatus 130 is moving to the destination. Here, a probe card 110 loaded into the first loading module 510 refers to a new probe card to be installed in the probe station 120.

The first loading module 510 may grip the probe cards 110 not to move while the probe card transporting apparatus 130 is on the move, but the present disclosure is not limited thereto. Alternatively, the first loading module 510 may use vacuum suction to hold the probe cards 110 in place on a flat surface, or may be designed in a basket shape to accommodate the probe cards 110 within its internal space.

The second loading module 520 provides a mounting surface where the probe cards 110 can be loaded, similar to the first loading module 510. However, the second loading module 520 does not load the probe cards 110 while the probe card transporting apparatus 130 is moving to the destination. This is because a probe card 110 loaded in the second loading module 520 is an old probe card to be replaced with the new probe card previously installed in the probe station 120. The new probe card will hereinafter be referred to as a first probe card, and the old probe card will hereinafter be referred to as a second probe card.

The hand gripper module 530 grips and loads and unloads the probe cards 110. If the first loading module 510 is for loading the first probe card and the second loading module 520 is for loading the second probe card, the hand gripper module 530 may unload the first probe card from the first loading module 510 and load the second probe card into the second loading module 520.

The robot arm module 540 includes the hand gripper module 530, which is provided at the end of the robot arm module 540, and controls the movement of the hand gripper module 530. The robot arm module 540 may control the hand gripper module 530 to move in a horizontal direction (or the first or second direction 10 or 20) and may also control the hand gripper module 530 to move in a vertical direction (or the third direction 30). Alternatively, the robot arm module 540 may control the hand gripper module 530 to move diagonally.

The hand gripper module 530 and the robot arm module 540 may be disposed above the first and second loading modules 510 and 520 for loading and unloading the first and second probe cards. However, if the loading/unloading of both the first and second probe cards is enabled, the hand gripper module 530 and the robot arm module 540 may be disposed either between the first and second loading modules 510 and 520 or below the first and second loading modules 510 and 520.

The support module 550 supports the first loading module 510, the second loading module 520, and the robot arm module 540 with the hand gripper module 530 installed at its end. The support module 550 may be installed on the housing H of the driving unit 310 with its length direction aligned in the vertical direction (or the third direction 30). The first loading module 510, the second loading module 520, and the robot arm module 540 may extend from different sides of the support module 550 and may be disposed on the housing H of the driving unit 310 with their length direction aligned in the horizontal direction (or the second direction 20).

The first and second loading modules 510 and 520 will hereinafter be described in further detail.

The first and second loading modules 510 and 520 may be disposed in the vertical direction (or the third direction 30). When viewed vertically from the top to the bottom, the first and second loading modules 510 and 520 may be disposed in the vertical direction to fully overlap with each other. Alternatively, the first and second loading modules 510 and 520 may be disposed in the vertical direction to partially overlap with each other. Yet alternatively, the first and second loading modules 510 and 520 may be disposed in the vertical direction not to overlap with each other.

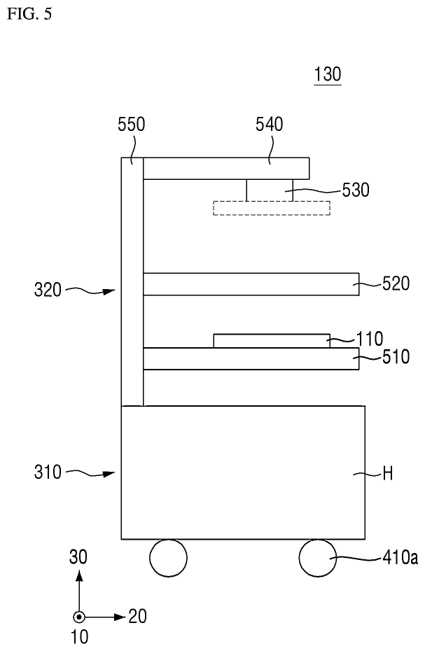

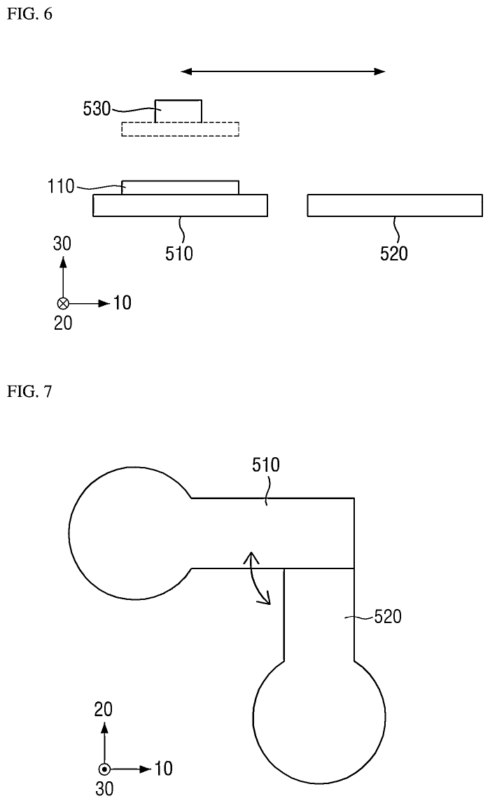

As previously described, the first loading module 510 may load a probe card 110 to be replaced, i.e., the first probe card, and the second loading module 520 may load the probe card 110 to be replaced, i.e., the second probe card. In this case, the first loading module 510 may be disposed on a higher level than the second loading module 520, but the present disclosure is not limited thereto. Alternatively, referring to FIG. 5, the first loading module 510 may be disposed on a lower level than the second loading module 520. Yet alternatively, referring to FIG. 6, the first and second loading modules 510 and 520 may be disposed on the same level. FIG. 5 is a second exemplary schematic view illustrating the internal configuration of the probe card transporting apparatus, and FIG. 6 is a third exemplary schematic view illustrating the internal structure of the probe card transporting apparatus.

Referring to FIG. 7, when the first loading module 510 is disposed on a higher level than the second loading module 520, the first loading module 510 may rotate in the horizontal direction (or the first or second direction 10 or 20). FIG. 7 illustrates an example where the first loading module 510 rotates in a leftward direction, but alternatively, the first loading module 510 may also rotate in a rightward direction.

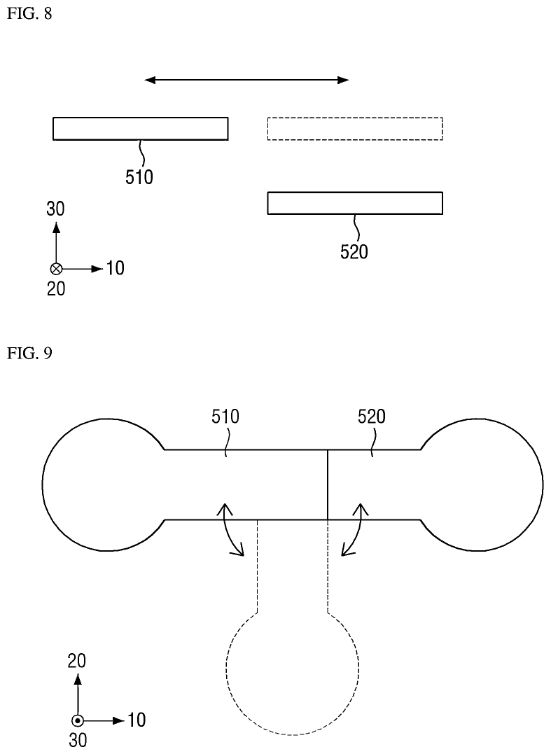

Yet alternatively, referring to FIG. 8, the first loading module 510 may move linearly in the horizontal direction (or the first direction 10). FIG. 8 illustrates an example where the first loading module 510 moves linearly in the leftward direction, but the first loading module 510 may also move linearly in the rightward direction.

If the first loading module 510 moves in a rotating or linear manner in the horizontal direction, the hand gripper module 530 may be allowed to load the second probe card onto the second loading module 520. FIG. 7 is a first exemplary schematic view illustrating the operating principle of the first loading module of the probe card transporting apparatus, and FIG. 8 is a second exemplary schematic view illustrating the operating principle of the first loading module of the probe card transporting apparatus.

When the first loading module 510 moves in a rotating or linear manner in the horizontal direction, the position of the second loading module 520 may be fixed, but the present disclosure is not limited thereto. Alternatively, the second loading module 520 may also move in a rotating or linear manner in the horizontal direction.

When the first and second loading modules 510 and 520 are both provided to be movable, the second loading module 520 may move in a different direction from the first loading module 510 to expose its top to the hand gripper module 530. For example, referring to FIG. 9, if the first loading module 510 rotates in the leftward direction, the second loading module 520 may rotate in the rightward direction, but the present disclosure is not limited thereto. Alternatively, the first loading module 510 may rotate in the rightward direction, while the second loading module 520 may rotate in the leftward direction. FIG. 9 is a first exemplary schematic view illustrating the operating principles of the first and second loading modules 510 and 520 of the probe card transporting apparatus 130.

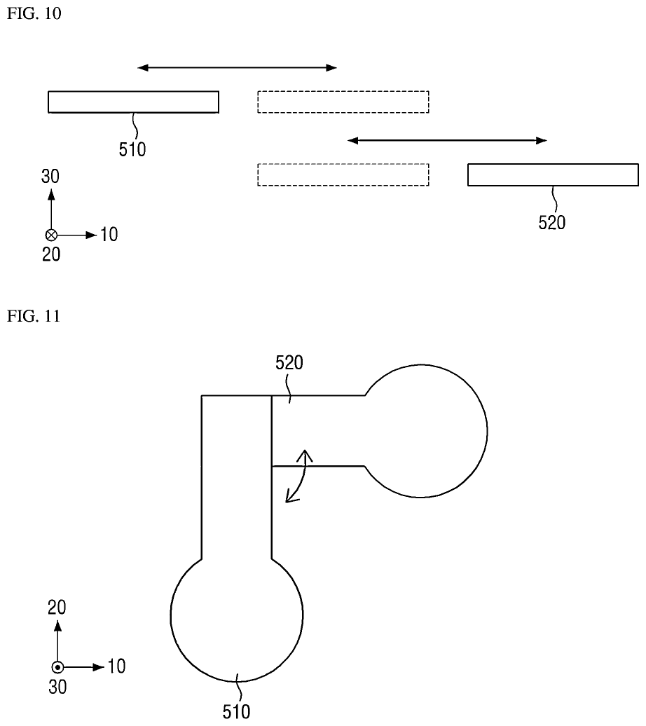

Alternatively, referring to FIG. 10, if the first loading module 510 moves linearly in the leftward direction, the second loading module 520 may move linearly in the rightward direction, but the present disclosure is not limited thereto. Alternatively, the first loading module 510 may move linearly in the rightward direction, while the second loading module 520 may move linearly in the leftward direction. FIG. 10 is a second exemplary schematic view illustrating the operating principles of the first and second loading modules of the probe card transporting apparatus.

Meanwhile, it is also possible that the second loading module 520 moves linearly in the rightward direction when the first loading module 510 rotates in the leftward direction. Additionally, it is also possible that the second loading module 520 rotates in the rightward direction when the first loading module 510 moves linearly in the leftward direction. Furthermore, it is also possible that the second loading module 520 moves linearly in the leftward direction when the first loading module 510 rotates in the rightward direction. Moreover, it is also possible that the second loading module 520 rotates in the leftward direction when the first loading module 510 moves linearly in the rightward direction.

The first loading module 510 may have a fixed position. In this case, to expose the second loading module 520, which is positioned below the first loading module 510, to the hand gripper module 530, the second loading module 520 may move. For example, referring to FIG. 11, the second loading module 520 may rotate in the horizontal direction (or the first or second direction 10 and 20). FIG. 11 illustrates an example where the second loading module 520 rotates in the rightward direction, but the second loading module 520 may also rotate in the leftward direction. FIG. 11 is a first exemplary schematic view illustrating the operating principle of the second loading module of the probe card transporting apparatus.

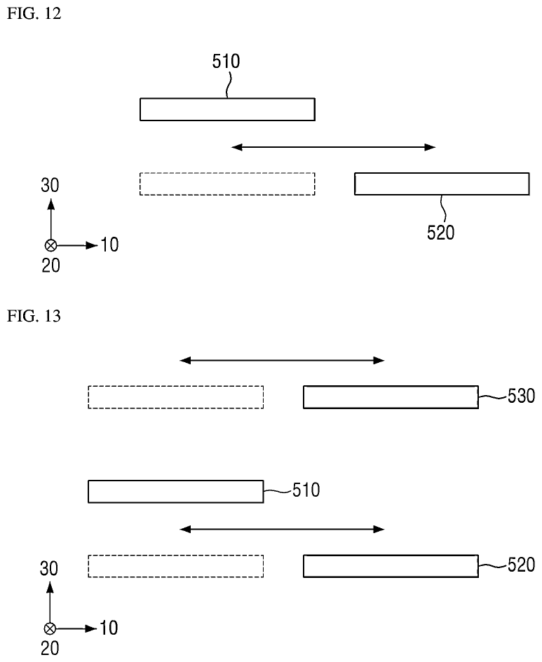

Alternatively, referring to FIG. 12, the second loading module 520 may move linearly in the horizontal direction (or the first direction 10). FIG. 12 illustrates an example where the second loading module 520 moves linearly in the rightward direction, but the second loading module 520 may also move linearly in the leftward direction. FIG. 12 is a second exemplary schematic view illustrating the operating principle of the second loading module of the probe card transporting apparatus.

When the second loading module 520 moves, the hand gripper module 530 may move along with the second loading module 520 to load the second probe card onto the second loading module 520. In this case, referring to FIG. 13, the hand gripper module 530 may move to a location corresponding to the location where the second loading module 520 has moved, in consideration of the movement direction and speed of the second loading module 520. FIG. 13 is an exemplary schematic view illustrating the operating principle of the hand gripper module of the probe card transporting apparatus.

When the first loading module 510 is disposed on a lower level than the second loading module 520, to expose the first loading module 510 to the hand gripper module 530, the first loading module 510 may move, while the second loading module 520 may have a fixed position. In this case, the first loading module 510 may rotate or move linearly in the same manner as the second loading module 520 of FIGS. 11 and 12.

Alternatively, to expose the first loading module 510 to the hand gripper module 530, the first and second loading modules 510 and 520 may both move. In this case, the first and second loading modules 510 and 520 may rotate or move linearly in different directions as depicted in FIGS. 9 and 10. It is also possible that one of the first and second loading modules 510 and 520 rotates while the other module moves linearly.

Alternatively, to expose the first loading module 510 to the hand gripper module 530, the second loading module 520 may move, while the first loading module 510 may have a fixed position. In this case, the second loading module 520 may rotate or move linearly in the same manner as the first loading module 510 of FIGS. 7 and 8.

When the first and second loading modules 510 and 520 are disposed on the same level, the first and second loading modules 510 and 520 may both be exposed to the hand gripper module 530. Thus, the first and second loading modules 510 and 520 may both remain fixed without moving, but the present disclosure is not limited thereto. It is also possible that at least one of the first and second loading modules 510 and 520 moves.

Meanwhile, when the first and second loading modules 510 and 520 are both exposed to the hand gripper module 530, it is not necessary for both the first and second loading modules 510 and 520 to be disposed at the same level. In other words, one of the first and second loading modules 510 and 520 may be disposed on a higher level than the other module. In this case, the first and second loading modules 510 and 520 may be disposed vertically not to overlap with each other, but it is also possible that the first and second loading modules 510 and 520 are disposed to partially overlap with each other as long as they can load and unload the probe cards 110.

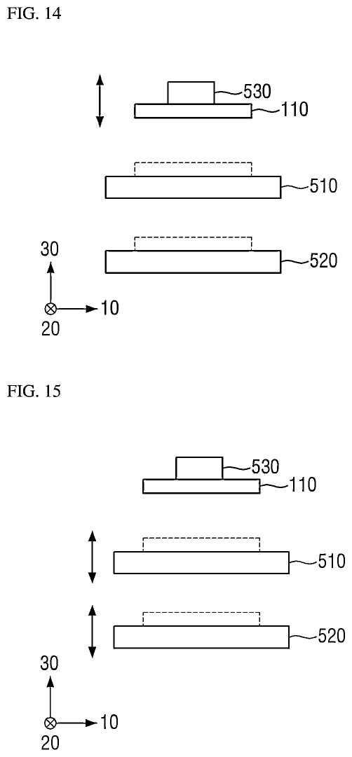

As previously described, the hand gripper module 530 may grip and load or unload the probe cards 110. In this case, referring to FIG. 14, the hand gripper module 530 may move in the vertical direction (or the third direction 30), approach the first loading module 510, and either unload the first probe card located on the first loading module 510 or load the second probe card onto the second loading module 520. FIG. 14 is a first exemplary schematic view illustrating the performance of the hand gripper module of the probe card transporting apparatus.

However, the present disclosure is not limited to this. Alternatively, referring to FIG. 15, if the first and second loading modules 510 and 520 move in the vertical direction to approach the hand gripper module 530, the hand gripper module 530 may unload the first probe card from the first loading module 510 or load the second probe card onto the second loading module 520. FIG. 15 is a second exemplary schematic view illustrating the performance of the hand gripper module of the probe card transporting apparatus.

FIG. 14 illustrates an example where the first and second loading modules 510 and 520 do not move in the vertical direction, and FIG. 15 illustrates an example where the hand gripper module 530 does not move in the vertical direction. However, the present disclosure is not limited to the examples of FIGS. 14 and 15. Alternatively, the first loading module 510, the second loading module 520, and the hand gripper module 530 may all be provided to be movable in the vertical direction, or either one of the first and second loading modules 510 and 520 and the hand gripper module 530 may be provided to be movable in the vertical direction.

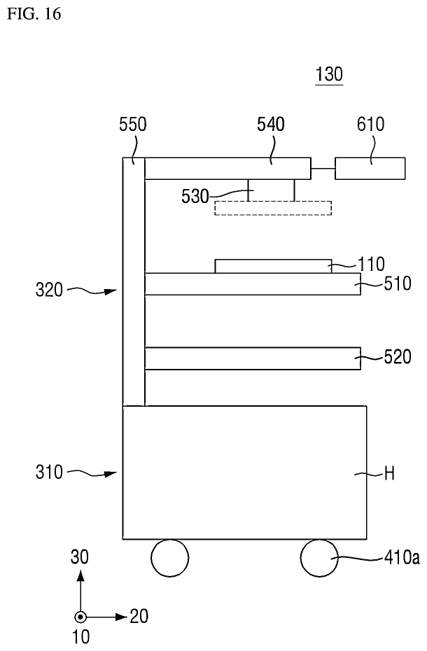

The manipulator unit 320 may further include a module for inspecting the mounting status of the probe cards 110. For example, referring to FIG. 16, the manipulator unit 320 may further include an image acquisition sensor 610. FIG. 16 is a first exemplary schematic view illustrating various functionalities of the manipulator unit of the probe card transporting apparatus.

When the first probe card is mounted on the first mounting module 510, the image acquisition sensor 610 may acquire an image that includes both the first loading module 510 and the first probe card. For example, the image acquisition sensor 610 may be provided as a vision sensor.

The image acquisition sensor 610 may be installed on the robot arm module 540 to acquire an image that includes both the first loading module 510 and the first probe card. However, the location of the image acquisition sensor 610 is not particularly limited as long as the image acquisition sensor 610 can properly measure the mounting status of the first probe card.

The image acquisition sensor 610 may be linked with the control module 450 of the driving unit 310. The control module 450 may determine whether the first probe card is properly mounted within the mounting surface of the first loading module 510 based on the image acquired by the image acquisition sensor 610.

As previously described, a control module that controls the overall operations of the components of the manipulation unit 320 may be provided separately from the control module 450 that controls the overall operations of the components of the driving unit 310. The control module 450 that controls the overall operations of the components of the driving unit 310 will hereinafter be referred to as a first control module, and the control module that controls the overall operations of the components of the manipulation unit 320 will hereinafter be referred to as a second control module. In this case, the image acquisition sensor 610 may be linked with the second control module, and the second control module may determine whether the first probe card is properly mounted within the mounting surface of the first loading module 510 based on the image acquired by the image acquisition sensor 610.

The image acquisition sensor 610 has been described as a sensor for determining whether the first probe card is properly mounted within the mounting surface of the first loading module 510, but the present disclosure is not limited thereto. The image acquisition sensor 610 may also determine whether the second probe card is properly mounted within the mounting surface of the second loading module 520.

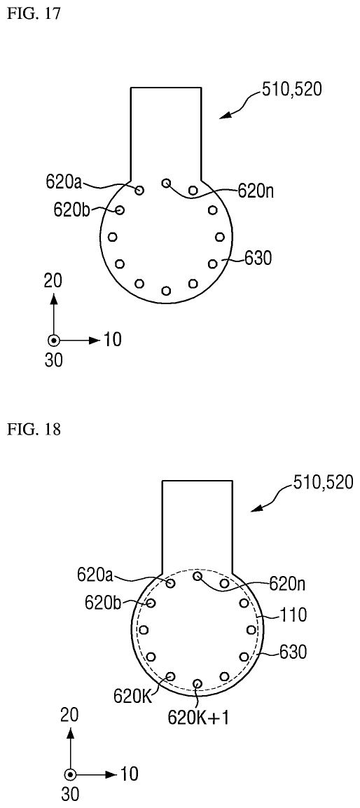

Referring to FIG. 17, the manipulation unit 320, which is a module for inspecting the mounting status of the probe cards 110, may further include a plurality of presence/absence sensors (620a, 620b, . . . , and 620n). FIG. 17 is a second exemplary view describing various functionalities of the manipulation unit of the probe card transporting apparatus.

The presence/absence sensors (620a, 620b, . . . , and 620n) may determine whether the first probe card is properly positioned on a mounting surface 630 of the first loading module 510 by measuring the distance between the mounting surface 630 of the first loading module 510 and the first probe card. Similarly, the presence/absence sensors (620a, 620b, . . . , and 620n) may determine whether the second probe card is properly positioned on a mounting surface 630 of the second loading module 520 by measuring the distance between the mounting surface 630 of the second loading module 520 and the second probe card. The presence/absence sensors (620a, 620b, . . . , and 620n) may be provided as, for example, ultrasonic sensors.

The presence/absence sensors (620a, 620b, . . . , and 620n) may be installed on the mounting surface 630 of the first or second loading module 510 or 520 to determine whether each probe card 110 is properly positioned on the first or second loading module 510 or 520. The presence/absence sensors (620a, 620b, . . . , and 620n), like the image acquisition sensor 610, may be linked with either the first or second control module, and the first or second control module may determine whether each probe card 110 is properly positioned on the mounting surface 630 based on the measurement results from the presence/absence sensors (620a, 620b, . . . , and 620n).

For example, referring to FIG. 18, if all the presence/absence sensors (620a, 620b, . . . , 620k, 620k+1, . . . , and 620n) are able to measure the distance between the first or second loading module 510 or 520 and a probe card 110 or the distance between the first or second loading module 510 or 520 and the probe card 110 is measured as being within a reference range, the first or second control module may determine that the probe card 110 is properly positioned on the mounting surface 630. FIG. 18 is a first exemplary schematic view illustrating how to determine whether the mounting status of a probe card is favorable.

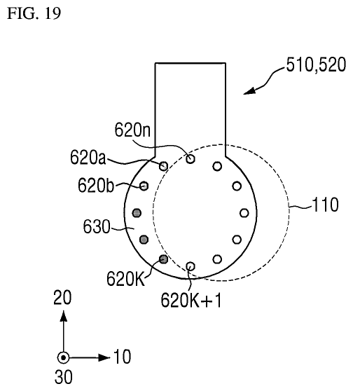

On the other hand, referring to FIG. 19, if some of the presence/absence sensors (620a, 620b, . . . , 620k, 620k+1, . . . , and 620n) fail to measure the distance between the first or second loading module 510 or 520 and a probe card 110 or the distance between the first or second loading module 510 or 520 and the probe card 110 is measured as being beyond the reference range, the first or second control module may determine that the probe card 110 is not properly positioned on the mounting surface 630. FIG. 19 is a second exemplary schematic view illustrating how to determine whether the mounting status of a probe card is favorable.

The probe card transporting apparatus 130, including the driving unit 310 and the manipulator unit 320, has been described so far with reference to FIGS. 3 through 19. The manipulator unit 320 may include two loading modules, i.e., the first and second loading modules 510 and 520, one hand gripper module 530, and one robot arm module 540. By using the first and second loading modules 510 and 520, the hand gripper module 530, and the robot arm module 540, the probe card transporting apparatus 130 can load and unload the probe cards 110 into and from the probe station 120.

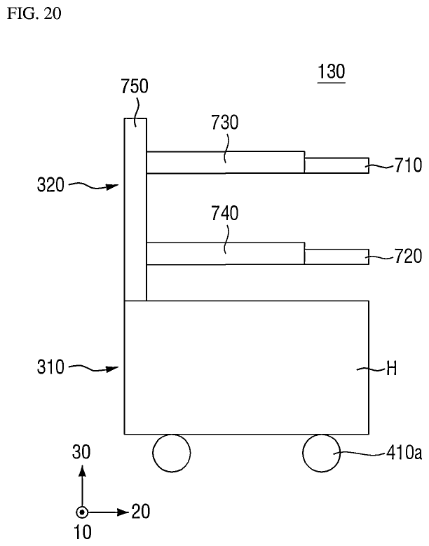

However, the present disclosure is not limited to this. Alternatively, the manipulator unit 320 may include two hand gripper modules and two robot arm modules to load or unload the probe cards 110 into or from the probe station 120. For example, referring to FIG. 20, the manipulator unit 320 may be configured to include a first hand gripper module 710, a second hand gripper module 720, a first robot arm module 730, a second robot arm module 740, and a support module 750.

In this example, the first and second hand gripper modules 710 and 720 may grip and load the probe cards 110. The first hand gripper module 710 may perform the functions carried out by both the first loading module 510 and the hand gripper module 530, and may adopt various structures and operations of the first loading module 510 and hand gripper module 530. Similarly, the second hand gripper module 720 may also perform the functions carried out by both the second loading module 520 and the hand gripper module 530, and may adopt various structures and operations of the second loading module 520 and the hand gripper module 530. FIG. 20 is a fourth exemplary schematic view illustrating the internal configuration of the probe card transporting apparatus of the system of FIG. 1.

The manipulator unit 320 may include a plurality of hand gripper modules. In this case, the hand gripper modules are connected to their respective robot arm modules, and the manipulator unit 320 may include the same number of robot arm modules and hand gripper modules.

The manipulator unit 320 may include different numbers of robot arm modules and hand gripper modules. For example, the manipulator unit 320 may have fewer robot arm modules compared to hand gripper modules. In this example, some hand gripper modules may be connected one-to-many to the same robot arm module, while other hand gripper modules may be connected one-to-one to different robot arm modules.

For example, in a case where the manipulator unit 320 includes the same number of robot arm modules and hand gripper modules, the manipulator unit 320 may include two hand gripper modules, i.e., the first and hand gripper modules 710 and 720, and two robot arm modules connected to their respective hand gripper modules, i.e., the first and second robot arm modules 730 and 740.

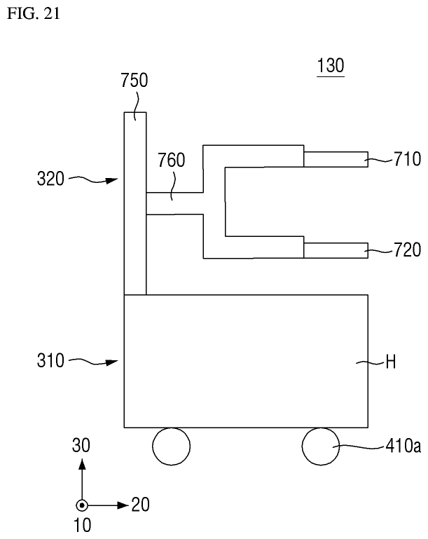

However, the present disclosure is not limited to this. In another example, referring to FIG. 21, in a case where the manipulator unit 320 includes different numbers of robot arm modules and hand gripper modules), the manipulator unit 320 may include two hand gripper modules, i.e., the first and second hand gripper modules 710 and 720, and the first and second hand gripper modules 710 and 720 may be connected to the same robot arm module, i.e., a third robot arm module 760. FIG. 21 is a fifth exemplary schematic view illustrating the internal configuration of the probe card transporting apparatus of the system of FIG. 1.

A method by which the probe card transporting apparatus 130 replaces the probe cards 110 at the probe station 120 will hereinafter be described.

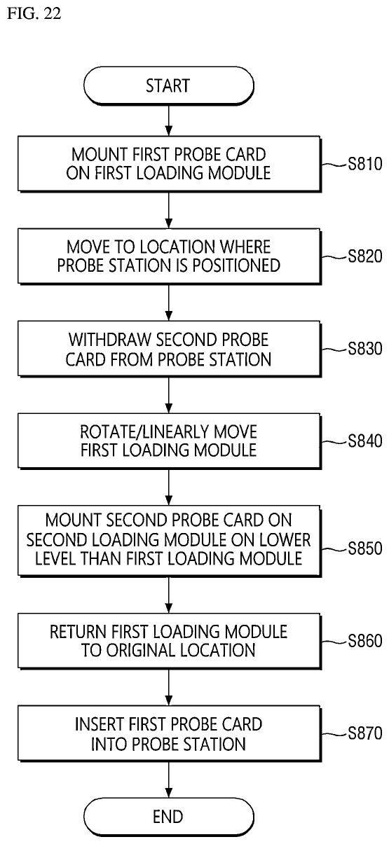

FIG. 22 is a flowchart illustrating a method of replacing probe cards according to a first embodiment of the present disclosure. The method of FIG. 22 may be performed by the probe card transporting apparatus 130 of FIG. 3.

Referring to FIGS. 3 and 22, the hand gripper module 530 loads a newly supplied first probe card onto the first loading module 510 under the control of the robot arm module 540 (S810). Here, the first probe card is an unused probe card to replace a second probe card installed in the probe station 120.

Thereafter, the driving unit 310 moves toward the location where the probe station 120 is positioned while carrying the first probe card on the first loading module 510 (S820).

Upon arriving at the location where the probe station 120 is positioned, the hand gripper module 530 directly withdraws the second probe card from the probe station 120 (S830), but the present disclosure is not limited thereto. Alternatively, a dedicated withdrawal/insertion robot may be provided within or near the probe station 120. If the second probe card is withdrawn by the dedicated withdrawal/insertion robot, the hand gripper module 530 may receive the second probe card from the dedicated withdrawal/insertion robot. Here, the second probe card is an already-used probe card to be replaced by the first probe card brought by the probe card transporting apparatus 130.

Thereafter, the first loading module 510 rotates or moves linearly so that the second loading module 520 can be exposed to the hand gripper module 530 (S840). Then, the hand gripper module 530 can load the second probe card onto the second loading module 520 (S850).

Once the second probe card is loaded onto the second loading module 520, the first loading module 510 returns to its original position through reverse rotation or linear movement (S860). The hand gripper module 530 then grips the first probe card previously mounted on the first loading module 510 and directly inserts the first probe card into the probe station 120 (S870). In this case, it is also possible that the hand gripper module 530 provides the first probe card to the dedicated withdrawal/insertion robot, which then directly inserts the first probe card to the probe station 120.

The method of FIG. 22 exemplifies a case where the first loading module 510, carrying the first probe card (or an unused probe card), is disposed on a higher level than the second loading module 520, carrying the second probe card (or an already-used probe card), but the present disclosure is not limited thereto. Alternatively, the first loading module 510 may also be disposed on a lower level than the second loading module 520, and this will hereinafter be described.

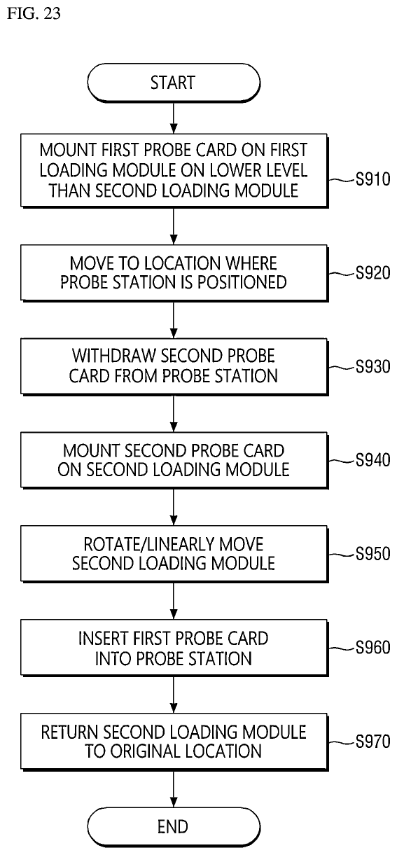

FIG. 23 is a flowchart illustrating a method of replacing probe cards according to a second embodiment of the present disclosure. The method in FIG. 23 may be performed by the probe card transporting apparatus 130 of FIG. 5.

Referring to FIGS. 5 and 23, under the control of the robot arm module 540, the hand gripper module 530 loads a newly supplied first probe card onto the first loading module 510 (S910). As mentioned earlier, the first probe card refers to an unused probe card.

Thereafter, the driving unit 310 moves toward the location where the probe station 120 is positioned while carrying the first probe card on the first loading module 510 (S920).

Thereafter, upon arriving at the location where the probe station 120 is positioned, the hand gripper module 530 directly withdraws a second probe card from the probe station 120 (S930). As mentioned earlier, it is also possible that the dedicated withdrawal/insertion robot withdraws the second probe card from the probe station 120. As previously described, the second probe card refers to an already-used probe card.

Thereafter, the hand gripper module 530 loads the second probe card onto the second loading module 520 (S940). Once the second probe card is loaded onto the second loading module 520, the second loading module 520 rotates or moves linearly so that the first loading module 510 can be exposed to the hand gripper module 530 (S950).

Thereafter, the hand gripper module 530 grips the first probe card, previously mounted on the first loading module 510, and directly inserts the first probe card into the probe station 120 (S960). When the hand gripper module 530, gripping the first probe card, rises to a higher level than the second loading module 520, the first loading module 510 returns to its original position through reverse rotation or linear movement (S970).

As previously described, the probe card transporting apparatus 130 is not limited to including a single hand gripper module 530 and two loading modules (510 and 520), as illustrated in FIG. 3. Alternatively, the probe card transporting apparatus 130 may include two hand gripper modules (710 and 720), as illustrated in FIG. 20.

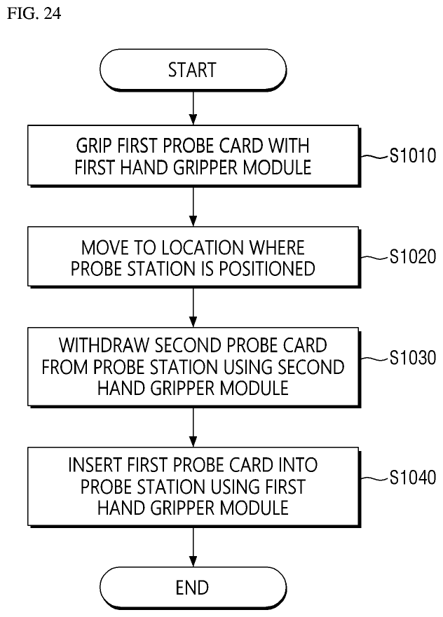

FIG. 24 is a flowchart illustrating a method of replacing probe cards according to a third embodiment of the present disclosure. The method of FIG. 24 may be performed by the probe card transporting apparatus 130 of FIG. 20.

Referring to FIGS. 20 and 24, the first hand gripper module 710 grips a newly supplied first probe card under the control of the first robot arm module 730 (S1010). Thereafter, for probe card replacement, the driving unit 310 moves to the location where the probe station 120 is positioned (S1020).

Upon arriving at the location where the probe station 120 is positioned, the second hand gripper module 720 directly withdraws a second probe card from the probe station 120 under the control of the second robot arm module (740) (S1030), but the present disclosure is not limited thereto. It is also possible that a dedicated withdrawal/insertion robot is separately provided within or near the probe station 120 and withdraws the second probe card from the probe station 120, and that the second hand gripper module 720 receives the second probe card from the dedicated withdrawal/insertion robot.

Thereafter, the first hand gripper module 710 directly inserts the first probe card into the probe station 120 (S1040). In this case, it is also possible that the first hand gripper module 710 provides the first probe card to the dedicated withdrawal/insertion robot, which then directly inserts the first probe card into the probe station 120.

The present disclosure relates to a two-tiered rotary loading feature for a probe card AMR with a rotatable upper loading section. The probe card AMR may include a rotary upper loading section for the simultaneously load/unloading of two probe cards, and a gripper may be provided to load a probe card onto each loading section.

Moreover, the present disclosure relates to a two-tiered movable loading feature for a probe card AMR. The probe card AMR may be provided in a manner that allows upper and lower loading sections and a gripper to move laterally to enable the simultaneous loading/unloading of two probe cards.

These probe card AMRs may include loading sections that enable the simultaneous loading/unloading of two probe cards. The probe card AMRs may be provided to allow for the replacement of test-completed probe cards at a probe station using a single AMR. The probe card AMRs may also be provided to work with multiple probe stations through a single route after loading multiple probe cards.

The former type of probe card AMR, i.e., the probe card AMR with the two-tiered rotary loading feature, may include a two-tiered loading structure where probe cards may be mounted. The probe card AMR may be designed to securely mount a probe card on each loading section. For upper-tier loading, the probe card AMR may be designed to move a gripper to load a probe card onto a fixed upper loading section. Conversely, for probe card lower-tier loading, the probe card AMR may be designed such that the upper loading section rotates to enable a probe card to be mounted on a lower loading section and to be loaded onto or unloaded from the lower loading section via the gripper.

The latter type of probe card AMR, i.e., the probe card AMR with the two-tiered movable loading feature, may also include a two-tiered loading section where probe cards may be mounted. The probe card AMR may be configured to securely mount a probe card on each loading section. For upper tier loading, a gripper may move to load a probe card onto a fixed upper loading section. For lower tier loading, the upper loading section and a lower loading section may move in opposite directions to enable loading and unloading, and the gripper may move to load or unload a probe card onto or from each loading section.

In summary, the characteristics of the aforementioned probe card AMRs are as follows. First, the probe card AMRs are autonomous AMRs that directly load and unload probe cards. Second, the probe card AMRs have a gripper at their top that can directly grip probe cards. Third, below the gripper, loading sections are provided where probe cards can be mounted. Fourth, the upper loading section can rotate for loading multiple probe cards or when the lower loading section is being used. Alternatively, the upper and lower loading sections can move in opposite directions for loading multiple probe cards. Fifth, the gripper can load or unload probe cards in accordance with the height of each loading section.

When two probe card transporting apparatuses access a probe station for the purpose of replacing probe cards, space needs to be secured around the probe station to allow the two probe card transporting apparatuses to access the probe station simultaneously. Additionally, two openings need to be formed in the probe station to allow the hand units of the two probe card transporting apparatuses to enter and exit, facilitating the import and export of probe cards.

To secure such space, the two probe card transporting apparatus may sequentially access the probe station for the import and export of probe cards. Alternatively, one probe card transporting apparatus may sequentially import and export probe cards. However, in such cases, a considerable amount of time may be consumed for replacing probe cards, potentially causing delays in the overall process time (also known as tact time).

On the contrary, according to embodiments of the present disclosure, each probe card transporting apparatus can load and unload a plurality of probe cards, thus not only having the effect of saving space but also having the effect of reducing the overall process time.

Moreover, by using a single probe card transporting apparatus device to perform probe card replacement within a probe station, other probe card transporting apparatuses can be utilized at other probe stations. This consequently has the effect of reducing the number of probe card transporting apparatuses deployed in a semiconductor fabrication plant.

The probe card transporting apparatus and method according to the present disclosure can be applied to the field of logistics automation within a semiconductor fabrication plant.

Embodiments of the present disclosure have been described above with reference to the accompanying drawings, but the present disclosure is not limited thereto and may be implemented in various different forms. It will be understood that the present disclosure can be implemented in other specific forms without changing the technical spirit or gist of the present disclosure. Therefore, it should be understood that the embodiments set forth herein are illustrative in all respects and not limiting.

What is claimed is:

1. A probe card transporting apparatus comprising:
a first loading module where a first probe card, which is a replacement probe card, is mounted;
a second loading module where a second probe card to be replaced is mounted; and
a hand gripper module withdrawing the second probe card from a probe station for semiconductor testing or inserting the first probe card into the probe station.

2. The probe card transporting apparatus of claim 1, wherein the first loading module is disposed on a higher level than the second loading module.

3. The probe card transporting apparatus of claim 2, wherein at least one of the first and second loading modules moves to the same level.

4. The probe card transporting apparatus of claim 3, wherein when the second probe card is mounted on the second loading module, the at least one of the first and second loading modules moves to the same level.

5. The probe card transporting apparatus of claim 3, wherein when the first and second loading modules both move, the first and second loading modules move in different directions.

6. The probe card transporting apparatus of claim 3, wherein the at least one of the first and second loading modules moves in one of a rotating manner and a linear manner.

7. The probe card transporting apparatus of claim 3, wherein when the second loading module moves, the hand gripper module also moves.

8. The probe card transporting apparatus of claim 1, wherein the hand gripper module is disposed on a higher level than the first and second loading modules.

9. The probe card transporting apparatus of claim 8, wherein the hand gripper module loads or unloads the first and second probe cards by descending to a level where the first and second loading modules are positioned.

10. The probe card transporting apparatus of claim 1, wherein the probe card transporting apparatus autonomously navigates to a location where the probe station is positioned.

11. The probe card transporting apparatus of claim 1, wherein
the first loading module is disposed on the same level as the second loading module, and
the first and second loading modules do not move.

12. The probe card transporting apparatus of claim 1, further comprising:
a sensor for inspecting whether the first probe card is mounted within a mounting surface of the first loading module.

13. The probe card transporting apparatus of claim 12, wherein the sensor is a sensor that acquires an image including the first loading module and the first probe card or a sensor that measures a distance between a surface of the first loading module and the first probe card.

14. The probe card transporting apparatus of claim 1, further comprising:
a robot arm module controlling the hand gripper module; and
a support module movably supporting the first loading module, the second loading module, and the robot arm module.

15. A probe card transporting apparatus comprising:
a first loading module where a first probe card, which is a replacement probe card, is mounted;
a second loading module where a second probe card to be replaced is mounted; and
a hand gripper module withdrawing the second probe card from a probe station for semiconductor testing or inserting the first probe card into the probe station,
wherein
when the first probe card is provided, the probe card transporting apparatus autonomously navigates to a location where the probe station is positioned,
the first loading module is disposed on a higher level than the second loading module and moves to one of a rotating manner and a linear manner when the second probe card is mounted on the second loading module, and
the hand gripper module is disposed on a higher level than the first and second loading modules and loads or unloads the first and second probe cards by descending to a level where the first and second loading modules are positioned.

16. A probe card transporting method comprising:
withdrawing, by a hand gripper module, a second probe card from a probe station;
moving a first loading module with a first probe card mounted therein;
loading, by the hand gripper module, the second probe card on a second loading module, which is disposed below the first loading module;
unloading, by the hand gripper module, the first probe card on the first loading module; and
inserting, by the hand gripper module, the first probe card into the probe station.

17. The probe card transporting method of claim 16, further comprising:
when the second probe card is mounted on the second loading module, returning the first loading module to its original location.

18. The probe card transporting method of claim 16, further comprising:
allowing the first loading module to autonomously navigate with the first probe card mounted therein to a location where the probe station is positioned.

19. The probe card transporting method of claim 16, wherein
the first probe card is an unused probe card, and
the second probe card is an already-used probe card.

20. The probe card transporting method of claim 18, wherein
the allowing the first loading module to autonomously navigate, comprises using a driving unit with the first loading module, the second loading module, and the hand gripper module installed in its upper part, and
the driving unit is provided as one of an automated guided vehicle (AGV) and an autonomous mobile robot (AMR).
